(19) United States
(12) Patent Application Publication
(10) Pub. No.: US 2014/0027167 A1
(43) Pub. Date: Jan. 30, 2014

(54) PRINTED CIRCUIT BOARD AND METHOD OF MANUFACTURING PRINTED CIRCUIT BOARD

(71) Applicant: SAMSUNG ELECTRO-MECHANICS CO., LTD., Suwon (KR)

(72) Inventors: Min Sung Kim, Suwon (KR); Yeo Wool Kim, Suwon (KR); Kyung Tae Kim, Suwon (KR); Duck Young Maeng, Suwon (KR); Hyun Chul Cho, Suwon (KR)

(21) Appl. No.: 13/920,991

(22) Filed: Jun. 18, 2013

(30) Foreign Application Priority Data
Jun. 18, 2012 (KR) 10-2012-0065050

(51) Int. Cl. H05K 1/11; H05K 3/46

(52) U.S. Cl. CPC H05K 1/119; H05K 3/4644
USPC 174/262; 29/852

(57) ABSTRACT

Disclosed herein is a printed circuit board, including: a first insulating layer; a second insulating layer formed on the first insulating layer; a first circuit patterns embedded in the first insulating layer; a first via formed on a top of the first circuit pattern and embedded in the first insulating layer; a second circuit pattern formed on the first via and the first insulating layer and embedded in the second insulating layer; a second via formed on the top of the second circuit pattern and embedded in the second insulating layer; and a third circuit pattern formed on the second insulating layer.

### CROSS REFERENCE TO RELATED APPLICATION

This application claims the benefit of Korean Patent Application No. 10-2012-0065050, filed on Jun. 18, 2012, entitled “Printed Circuit Board and Method of Manufacturing for Printed Circuit Board,” which is hereby incorporated by reference in its entirety into this application.

### BACKGROUND OF THE INVENTION

1. Technical Field

The present invention relates to a printed circuit board and a method of manufacturing the printed circuit board.

2. Description of the Related Art

Recently, a trend of multifunctional and high-speed electronic products has progressed at a rapid speed. In accordance with such a trend, semiconductor chips and printed circuit boards in which semiconductor chips are mounted also have progressed at a rapid speed. Such printed circuit boards are required to be light, thin and simple, while being implemented as microcircuits, in addition to have good electric property, high reliability, and high speed signal transmission.

In the prior art, a core substrate having a core layer inserted therein has been commonly used so as to prevent warpage of a printed circuit board. However, the core substrate has shortcomings due to thick thickness and a long signal processing time (see US Patent Laid-Open Publication No. 2004/0058136).

### SUMMARY OF THE INVENTION

The present invention has been made in an effort to provide a printed circuit board and a method of manufacturing the printed circuit board in which a solder resist process may be omitted.

Further, the present invention has been made in an effort to provide a printed circuit board capable of eliminating warpage thereof and a method of manufacturing the printed circuit board. According to a first preferred embodiment of the present invention, there is provided a printed circuit board, including: a first insulating layer; a second insulating layer formed on the first insulating layer; a first circuit patterns embedded in the first insulating layer; a first via formed on a top of the first circuit pattern and embedded in the first insulating layer; a second circuit pattern formed on the first via and the first insulating layer and embedded in the second insulating layer; a second via formed on a top of the second circuit pattern and embedded in the second insulating layer; and a third circuit pattern formed on the second insulating layer.

The first insulating layer and the second insulating layer may be formed of prepreg.

The first via may be formed between the first circuit pattern and the second circuit pattern so as to connect them to each other.

The second via may be formed between the second circuit pattern and the third circuit pattern so as to connect them to each other.

The bottom of the first circuit pattern may be exposed to the outside of the first insulating layer.

The printed circuit board may further include a surface finish layer formed on the bottom of the first circuit pattern.

The printed circuit board may further include a surface finish layer formed on the top of the third circuit pattern.

According to a second preferred embodiment of the present invention, there is provided a method of manufacturing a printed circuit board, the method including: preparing a carrier substrate; forming first patterns on upper and lower surfaces of the carrier substrate; forming first insulating layers over the first circuit patterns; forming first vias on tops of the first circuit patterns; forming second circuit patterns on the first insulating layers; forming second insulating layers over the first insulating layers and the second circuit patterns; forming second vias on tops of the second insulating layers; forming third patterns on the second vias; and removing the carrier substrate.

The first insulating layer and the second insulating layer may be formed of prepreg.

The method may further include forming a surface finish layer on the third circuit pattern after the removing of the carrier substrate.

In the removing of the carrier substrate, the bottom of the first circuit pattern may be exposed to the outside of the first insulating layer.

The method may further include forming a surface finish layer on the bottom of the first circuit pattern after the removing of the carrier substrate.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a printed circuit board according to a preferred embodiment of the present invention; and

FIGS. 2 to 10 are views illustrating a method of manufacturing a printed circuit board according to a preferred embodiment of the present invention.

FIG. 11 is a view showing a surface finish layer may be formed.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

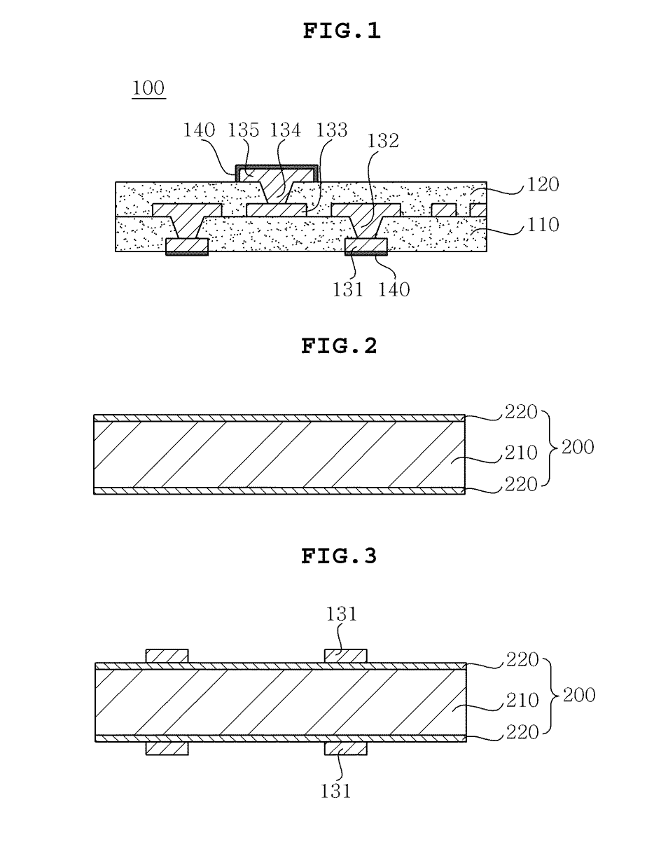

FIG. 1 is a view showing a printed circuit board according to a preferred embodiment of the present invention.

Referring to FIG. 1, the printed circuit board 100 may be configured to include a first insulating layer 110, a first circuit pattern 131, a first via 132, a second insulating layer 120, a second circuit pattern 133, a second via 134, a third circuit pattern 135 and a surface finish layer 140.

The first insulating layers 110 may be formed of prepreg. The first insulating layer 110 may have the first circuit pattern 131 and the first via 132 embedded therein.

The first circuit pattern 131 may be formed in the first insulating layer 110. Here, the bottom of the first circuit pattern 131 may be exposed to the outside of the first insulating layer 110.

The first via 132 may be formed in the first insulating layer 110. The first via holes 132 may be formed on the top of the first circuit pattern 131. That is, the first via 132 may be electrically connected to the first circuit pattern 131.

The second insulating layer 120 may be formed over the via 132 and the first insulating layer 110. The second insulating layer 120 may be formed of prepreg. The first insulating layer 110 may have the second circuit pattern 133 and the second via 134 embedded therein.

The second circuit pattern 133 may be formed in the second insulating layer 120. In addition, the second circuit pattern 133 may be formed on the first via 132. That is, the second pattern 133 may be electrically connected to the first via 132.

The second via 134 may be formed in the second insulating layer 120. The second via holes 134 may be formed on the top of a second circuit pattern 133. That is, the second via 134 may be electrically connected to the second circuit pattern 133.

A third circuit pattern 135 may be formed on the second via 134. In addition, the third circuit pattern 135 may be formed on the second insulating layer 120. The third circuit pattern 135 may be formed on the second via 134 so as to be electrically connected to the second via 134. The third pattern 135 may be formed on the second insulating layer 120 so as to be exposed to the outside. For instance, the third circuit pattern 135 may be a contact pad electrically connected to an external electronic component.

In the preferred embodiment of the present invention, the first circuit pattern 131, the first via 132, the second circuit pattern 133, the second via 134 and the third circuit pattern 135 may be formed of conductive material such as conductive paste or metal. For example, the conductive material may be copper. However, the conducive material is not limited to copper as long as the same function is obtained.

The surface finish layer 140 may be formed on the first circuit pattern 131 and the third circuit pattern 135. The surface finish layer 140 may be formed in order to improve the electric characteristics and the durability of the first circuit pattern 131 and the third circuit pattern 135 exposed to the outside. The surface finish layer 140 may be formed on the bottom of the first circuit pattern 131 exposed to the outside of the first insulating layer 110. In addition, the surface finish layer 140 may be formed on the top of the third circuit pattern 135 exposed to the outside of the second insulating layer 120. The surface finish layer 140 may be formed by performing electrolyte- or electroless tin plating, OSP, or and HASL method on the surfaces of the third circuit pattern 135 and the first circuit pattern 131 exposed to the outside.

The printed circuit board 100 according to the preferred embodiment of the present invention may have the configuration in which the first circuit pattern 131, the second circuit pattern 133, the first via 132 and the second via 134 may be embedded in the first insulating layer 110 and the second insulating layer 120, except for the third circuit pattern 135. In addition, according to the preferred embodiment of the present invention, the circuit patterns 131 and 133 and the vias 132 and 134 are embedded in and protected by the insulating layers 110 and 120, such that no separate solder resist is required for soldering. In particular, the prepreg, which forms the insulating layers 110 and 120, contains glass fabric unlike ordinary solder resists and thus is less flexible and more rigid than solder resists. That is, according to the preferred embodiment of the present invention, solder resists are replaced by the insulating layers 110 and 120 which are less flexible and more rigid than solder resists, thereby reducing warpage of a printed circuit board.

FIGS. 2 to 10 are views showing a method of manufacturing a printed circuit board according to a preferred embodiment of the present invention.

Referring to FIG. 2, a carrier substrate 200 is prepared. The carrier substrate 200 may include a carrier insulating layer 210 and carrier metal foils 220 formed on both surfaces of the carrier insulating layer 210. The carrier insulating layer 210 may be formed of an epoxy resin or fluorine resin. Alternatively, the carrier insulating layer 210 may be formed of prepreg. The carrier metal foils formed on both surfaces of the carrier insulating layer 210 may be formed of copper. However, material of the carrier metal foils 220 is not limited to copper as long as the material used has the same property.

Referring to FIG. 3, first circuit patterns 131 may be formed on upper and lower surfaces of the carrier substrate 200.

The first circuit patterns 131 may be formed by forming plating resists (not shown) on upper surfaces of the carrier substrate 200, performing electroless plating and electrolyte plating, and then removing the plating resists (not shown). The first circuit patterns 131 may be made of a conductive material. For example, the first circuit pattern 131 may be formed of copper.

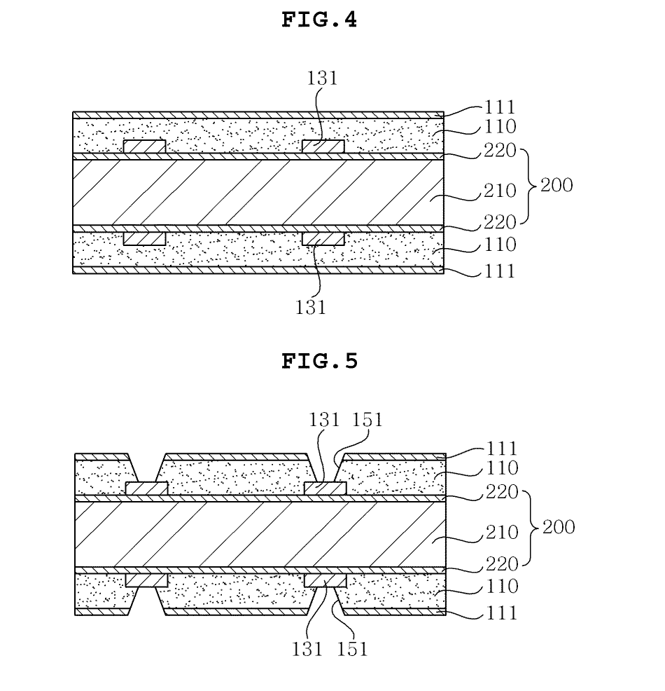

Referring to FIG. 4, first insulating layers 110 may be formed over the first circuit patterns 131 and the carrier substrate 200. The first metal layers 110 may be formed of prepreg. Here, first metal foils 111 may be formed on the prepreg. The first metal foils 111 formed on the prepreg may be formed of copper. However, material of the first metal foils 111 are not limited to copper as long as the metal foil used has the same property.

Referring to FIG. 5, first via holes 151 may be formed in the first insulating layers 110. The first via holes 151 may be formed on tops of the first circuit patterns 131. The first via holes 151 may be formed using a CNC drill, a laser drill, or the like. The tops of the first circuit patterns 131 may be exposed through the first via holes 151 thus formed.

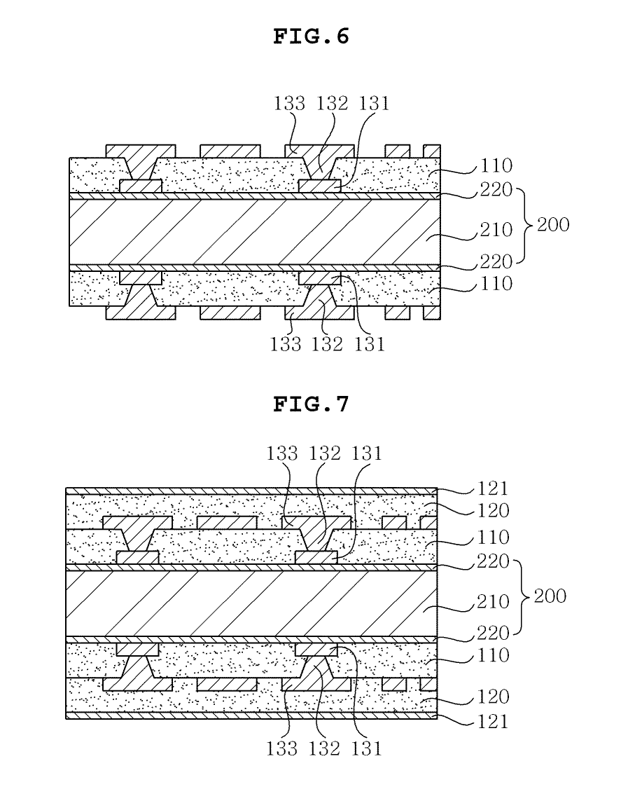

Referring to FIG. 6, first vias 132 and second circuit patterns 133 may be formed. The first metal foils 111 formed on the first insulating layer 110 may be removed prior to forming the first vias 132 and the second circuit patterns 133. After removing the first metal foils 111, the first via holes 151 may be filled with conductive material to form the first vias 132. Then, the second circuit patterns 133 may be formed on the first vias 132 or on the first insulating layers 110. Here, the first vias 132 and the second circuit patterns 133 may be filled with conductive paste. Further, the first vias 132 and the second circuit patterns 133 may be formed by electroless plating and electrolyte plating. Here, the first vias 132 and the second circuit patterns 133 may be formed of copper. However, the present invention is not limited thereto. That is, any conductive material may be used for plating other than copper. Further, the second circuit patterns 133 may be formed by patterning the first metal foils 111. However, forming methods of the first vias 132 and the second circuit patterns 133 are not limited thereto. The first vias 132 and the second circuit patterns 133 may be formed by any of the known techniques.

Referring to FIG. 7, second insulating layers 120 may be formed over the second circuit patterns 133 and the first insulating layers 110. The second insulating layers 120 may be formed of prepreg. Here, the second metal foils 121 may be formed on the prepreg. The second metal foils 121 formed on the prepreg may be formed of copper. However, material of the second metal foils 121 is not limited to copper as long as the metal foil used has the same property.

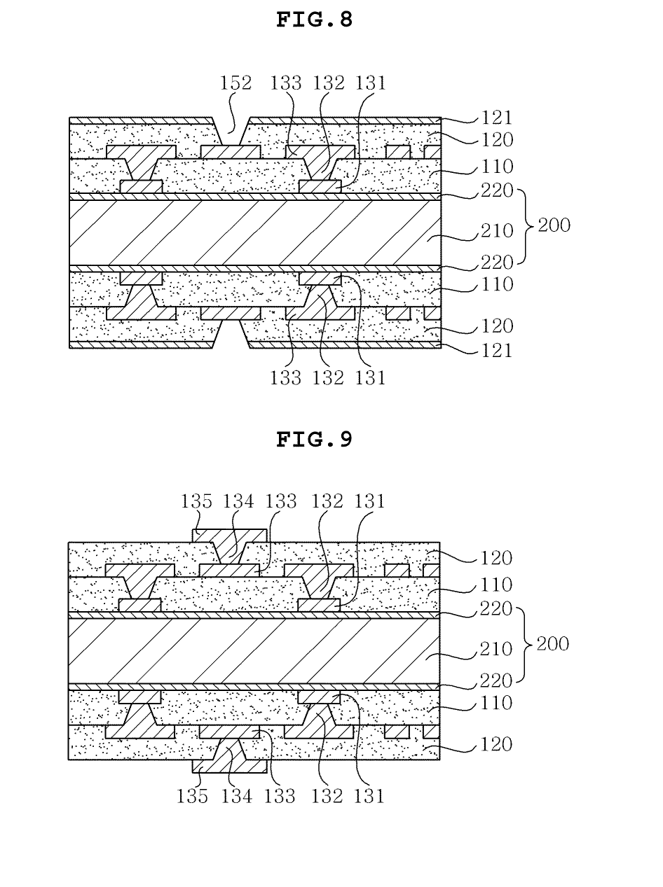

Referring to FIG. 8, second via holes 152 may be formed in the second insulating layers 120. The second via holes 152 may be formed on tops of second circuit patterns 133. The second via holes 152 may be formed using a CNC drill, a laser drill, or the like. The tops of the second circuit patterns 133 may be exposed through the second via holes 152 thus formed.

Referring to FIG. 9, second vias 134 and third circuit patterns 135 may be formed. The second metal foils 121 formed on the second insulating layers 120 may be removed prior to forming the second vias 134 and the third circuit patterns 135. After removing the second metal foils 121, the second via holes 152 may be filled with conductive material to form the second vias 134. Then, the third circuit patterns 135 may be formed on the second vias 134 or on the second insulating layers 120. Here, the second vias 134 and the third circuit patterns 135 may be filled with conductive paste. Here, the second vias 134 and the third circuit patterns 135 may be formed by a electroless plating process and electrolyte plating process. Here, the second vias 134 and the third circuit patterns 135 may be formed of copper. However, the present invention is not limited thereto. That is, any conductive material may be used for plating other than copper. Further, the third circuit patterns 135 may be formed by patterning the second metal foils 121.

However, forming methods of the second vias 134 and the third circuit patterns 135 are not limited thereto. The second vias 134 and the third circuit patterns 135 may be formed by any of the known techniques.

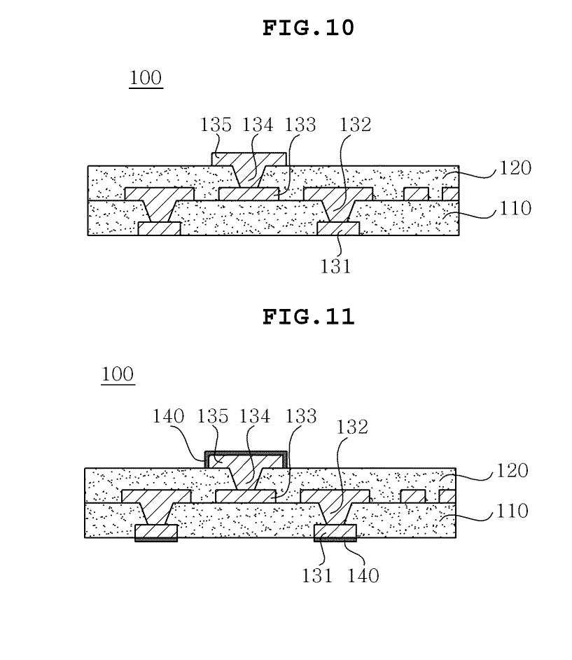

Referring to FIG. 10, the carrier substrate 200 may be removed. By removing the carrier substrate 200, the printed circuit board formed on the carrier substrate 200 and the printed circuit board formed under the carrier substrate 200 may be separated from the carrier substrate 200. FIG. 10 shows one of the printed circuit boards 100 separated from the carrier substrate 200. The other printed circuit board separated from the carrier substrate 200 may also have the same shape with the one shown in FIG. 10.

In order to remove the carrier substrate 200, firstly, the carrier insulating layers 210 may be separated from the carrier metal foils 220. Then, the carrier metal foils 220 attached under the printed circuit board 100 separated from the carrier insulating layer 210 may be removed. The process of removing the carrier substrate 200 is well known in the art and the detailed description thereon is omitted.

The printed circuit board 100 separated from the carrier substrate 200 may have the configuration in which the first circuit patterns 131, the second circuit patterns 133, the first vias 132 and the second vias 134 may be embedded in the first insulating layers 110 and the second insulating layers 120, except for the third circuit patterns 135.

Referring to FIG. 11, a surface finish layer 140 may be formed on the first circuit pattern 131 and the third circuit pattern 135 exposed to the outside of the first insulating layer 110 and the second insulating layer 120.

In FIG. 10, by removing the carrier metal foil 220, the bottom of the first circuit pattern 131 formed in the first insulating layer 110 may be exposed to the outside. In addition, the third pattern 135 may be formed on the second insulating layer 120 so as to be exposed to the outside. The surface finish layer 140 may be formed in order to improve the electric characteristics and the durability of the third circuit pattern 135 and the first circuit pattern 131 exposed to the outside. The surface finish layer 140 may be formed by performing electrolyte- or electroless tin plating, OSP, or an HASL method on the surfaces of the third circuit pattern 135 and the first circuit pattern 131 exposed to the outside.

According to the printed circuit board and the method of manufacturing the printed circuit board according to the preferred embodiments of the present invention, the first circuit patterns, the second circuit patterns, the first vias and the second vias may be embedded in the first insulating layers and the second insulating layers, except for the third circuit patterns. As described above, the circuit patterns are embedded in the insulating layers so that solder resists to be used for protecting the circuit patterns may be omitted.

In addition, according to the preferred embodiment of the present invention, the circuit patterns and the vias are embedded in and protected by the insulating layers, such that no separate solder resist is required for soldering. In particular, the prepreg, which forms the insulating layers, contains glass fabric unlike ordinary solder resists and thus is less flexible and more rigid than solder resists. That is, according to the preferred embodiment of the present invention, solder resists are replaced by the insulating layers which are less flexible and more rigid than solder resists, thereby reducing warpage of a printed circuit board.

Although an example has been described in which a printed circuit board has a three-tier structure for the sake of convenience, the present invention is not limited thereto. As appreciated by those skilled in the art, the present invention is applicable to a printed circuit board having circuit patterns of a more than three-tier structure.

As described above, in the printed circuit board and the method of manufacturing the printed circuit board, since the circuit patterns are embedded in the insulating layers, solder resists for protecting circuit patterns can be omitted at the time of soldering.

Further, in the printed circuit board and the method of manufacturing the printed circuit board, by replacing solder resists with insulating layers which are less flexible and more rigid than solder resists, warpage of a printed circuit board can be reduced.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a first insulating layer;
a second insulating layer formed on the first insulating layer;
a first circuit patterns embedded in the first insulating layer;
a first via formed on a top of the first circuit pattern and embedded in the first insulating layer;
a second circuit pattern formed on the first via and the first insulating layer, and embedded in the second insulating layer;
a second via formed on a top of the second circuit pattern, and embedded in the second insulating layer; and
a third circuit pattern formed on the second insulating layer.

2. The printed circuit board as set forth in claim 1, wherein the first insulating layer and the second insulating layer are formed of prepreg.

3. The printed circuit board as set forth in claim 1, wherein the first via is formed between the first circuit pattern and the second circuit pattern so as to electrically connect them to each other.

4. The printed circuit board as set forth in claim 1, wherein the second via is formed between the second circuit pattern and the third circuit pattern so as to electrically connect them to each other.

5. The printed circuit board as set forth in claim 1, wherein a bottom of the first circuit pattern is exposed to the outside of the first insulating layer.

6. The printed circuit board as set forth in claim 5, further comprising a surface finish layer formed on the exposed bottom of the first circuit pattern.

7. The printed circuit board as set forth in claim 1, further comprising a surface finish layer formed on a top of the third circuit pattern.

8. A method of manufacturing a printed circuit board, the method comprising:
preparing a carrier substrate;
forming first circuit patterns on upper and lower surfaces of the carrier substrate;
forming first insulating layers over the first circuit patterns;
forming first vias on tops of the first circuit patterns;
forming second circuit patterns on the first insulating layers;
forming second insulating layers over the first insulating layers and the second circuit patterns;
forming second vias on tops of the second insulating layers;
forming third patterns on the second vias; and
removing the carrier substrate.

9. The method as set forth in claim 8, wherein the first insulating layer and the second insulating layer are formed of prepreg.

10. The method as set forth in claim 8, further comprising forming a surface finish layer on tops of the third circuit patterns, after the removing of the carrier substrate.

11. The method as set forth in claim 8, where in the removing of the carrier substrate, bottoms of the first circuit patterns are exposed to the outside of the first insulating layers.

12. The method as set forth in claim 11, further comprising forming a surface finish layer on the exposed bottoms of the first circuit patterns, after the removing of the carrier substrate.
